(19) United States
(12) Patent Application Publication
(10) Pub. No.: US 2025/0011612 A1
(43) Pub. Date: Jan. 9, 2025

(54) ELECTROCONDUCTIVE INK COMPOSITIONS AND ELECTROCONDUCTIVE FILM

(71) Applicant: Lion Specialty Chemicals Co., Ltd., Tokyo (JP)

(72) Inventors: Hiromu SATO, Tokyo (JP); Kasumi MUKAIDA, Tokyo (JP)

(73) Assignee: Lion Specialty Chemicals Co., Ltd., Tokyo (JP)

(21) Appl. No.: 18/713,152

(22) PCT Filed: Nov. 15, 2022
(86) PCT No.: PCT/JP2022/042358

§ 371 Date: May 23, 2024

(30) Foreign Application Priority Data
Nov. 25, 2021 (JP) JP2021-191276
Nov. 25, 2021 (JP) JP2021-191277

(51) Int. Cl. C09D 11/52; C09D 11/037; C09D 11/107; G01L 5/1623

(52) U.S. Cl. CPC C09D 11/52; C09D 11/037; C09D 11/107; G01L 5/1623

(57) ABSTRACT

A conductive ink composition contains a (meth)acrylic polymer (A) and silver particles (B). The (meth)acrylic polymer (A) has a glass transition temperature of ≤0° C., a weight average molecular weight of ≥500,000, and a hydroxyl value of more than 50 mgKOH/g. The silver particles (B) have a specific surface area of 0.5 to 3.0 m²/g, a 50% average particle diameter of 0.5 to 14.0 μm, a maximum particle diameter of ≥8 μm, and a solid content from 50 to 80% by mass. Another conductive ink composition contains a (meth)acrylic polymer (A) and carbon black (CB). The (meth)acrylic polymer (A) has a glass transition temperature of ≤0° C., a weight average molecular weight of ≥500,000, and a hydroxyl value of more than 50 mgKOH/g. The carbon black (CB) has a specific surface area of ≥50 m²/g, an aggregate diameter of ≤400 nm, and a solid content from 15 to 30% by mass.

### TECHNICAL FIELD

The present invention relates to a conductive ink composition and a conductive film using the conductive ink composition.

Priority is claimed on Japanese Patent Application No. 2021-191276 and Japanese Patent Application No. 2021-191277, filed Nov. 25, 2021, the contents of which are incorporated herein by reference.

### BACKGROUND ART

In recent years, printed electronics (PE) in which a conductive film is formed by a printing method using a conductive ink has been attracting attention in the field of electronic device production. By using PE, for example, it is possible to produce a flexible device by forming a conductive film on a thin base material.

Patent Document 1 proposes a method in which, in a flexible circuit board where electrodes and wiring can be expanded and contracted (elastic), for the purpose of reducing changes in electrical resistance due to expansion and contraction, a filler metal of a specific shape is filled into an elastomer having a functional group capable of forming a hydrogen bond and a glass transition temperature of −10° C. or lower, and a flake-shaped or needle-shaped filler metal is oriented along the direction of expansion and contraction of a film and is brought into contact with a lump-shaped filler metal to ensure conduction.

### CITATION LIST

### Patent Document

[Patent Document 1] Japanese Unexamined Patent Application, First Publication No. 2010-153364

### SUMMARY OF INVENTION

### Technical Problem

According to the findings by the inventors of the present invention and the like, sufficient elongation may not be achieved using the method described in Patent Document 1.

The present invention has an object of providing a conductive ink composition capable of forming a conductive film that is elastic and exhibits excellent electrical conductivity when stretched.

### Solution to Problem

The present invention includes the following aspects.

[1-1] A conductive ink composition containing: a (meth)acrylic polymer (A) and silver particles (B), wherein the aforementioned (meth)acrylic polymer (A) has a glass transition temperature of 0° C. or less, a weight average molecular weight of 500,000 or more, and a hydroxyl value of more than 50 mgKOH/g, the aforementioned silver particles (B) have a specific surface area of 0.5 to 3.0 m²/g, a 50% average particle diameter of 0.5 to 14.0 m, and a maximum particle diameter of 8 m or more, and a solid content is from 50 to 80% by mass.

[1-2] The conductive ink composition according to [1-1], wherein the aforementioned (meth)acrylic polymer (A) has a glass transition temperature of more than −50° C. and less than −30° C., and a weight average molecular weight of 500,000 to 990,000.

[1-3] The conductive ink composition according to [1-1] or [1-2], wherein a content of a unit (a1) based on a hydroxyl group-containing monomer is from 20 to 40% by mass with respect to all units constituting the aforementioned (meth)acrylic polymer (A).

[1-4] The conductive ink composition according to any one of [1-1] to [1-3], which has a viscosity at 23° C. of 20 to 50 Pa-s.

[1-5] A conductive film obtained by drying a coating film of the conductive ink composition according to any one of [1-1] to [1-4] above.

[1-6] The conductive film according to [1-5], which is used for an electrode or wiring that requires elasticity in an electronic device.

[1-7] The conductive film according to [1-5], which is used for a detection part, electrode, or wiring of a variable resistance sensor.

[2-1] A conductive ink composition containing: a (meth)acrylic polymer (A) and carbon black (CB), wherein the aforementioned (meth)acrylic polymer (A) has a glass transition temperature of 0° C. or less, a weight average molecular weight of 500,000 or more, and a hydroxyl value of more than 50 mgKOH/g, the aforementioned carbon black (CB) has a specific surface area of 50 m²/g or more, and an aggregate diameter of 400 nm or less, and a solid content is from 15 to 30% by mass.

[2-2] The conductive ink composition according to [2-1], wherein the aforementioned (meth)acrylic polymer (A) has a glass transition temperature of more than −50° C. and less than −30° C., and a weight average molecular weight of 500,000 to 990,000.

[2-3] The conductive ink composition according to [2-1] or [2-2], wherein a content of a unit (a1) based on a hydroxyl group-containing monomer is from 20 to 40% by mass with respect to all units constituting the aforementioned (meth)acrylic polymer (A).

[2-4] The conductive ink composition according to any one of [2-1] to [2-3], which has a viscosity at 23° C. of 20 to 100 Pa-s.

[2-5] A conductive film obtained by drying a coating film of the conductive ink composition according to any one of [2-1] to [2-4] above.

[2-6] The conductive film according to [2-5], which is used for an electrode or wiring that requires elasticity in an electronic device.

[2-7] The conductive film according to [2-5], which is used for a detection part, electrode, or wiring of a variable resistance sensor.

### Advantageous Effects of Invention

According to the conductive ink composition of the present invention, it is possible to form a conductive film that is elastic and exhibits excellent electrical conductivity when stretched.

The following definitions of terms apply throughout the present specification and claims.

A numerical range represented by a symbol “-” means a numerical range having numerical values before and after this symbol “-” as the lower limit and upper limit values.

The term “(meth)acrylate” is a generic term for acrylate and methacrylate, and the term “(meth)acrylic” is a generic term for “acrylic” and “methacrylic.”

A “unit” of a polymer means an atomic group (monomer unit) formed from one monomer molecule.

The weight average molecular weight (Mw) of a polymer is a polystyrene equivalent molecular weight obtained by measurement by gel permeation chromatography using a calibration curve produced using a standard polystyrene sample with a known molecular weight. More specifically, it can be determined, for example, by using “Alliance E2695 Separation Module” (product name) manufactured by Nihon Waters K. K. as a GPC measuring device, and measuring a polystyrene equivalent value under the following GPC measurement conditions.

### (GPC Measurement Conditions)

Sample concentration: 0.5% by weight (tetrahydrofuran solution)
Sample injection volume: 20 L
Eluent: tetrahydrofuran (THF)
Flow rate (flow velocity): 0.3 mL/min
Column temperature (measurement temperature): 40° C.
Column: “TSKguard column HSPgel RT-MB-H+HSPgel RT-2.0” (product name, manufactured by Tosoh Corporation)
Detector: differential refractometer (RI), “Alliance 2414” (product name, manufactured by Nihon Waters K. K.)

A hydroxyl value (unit: mgKOH/g) of a polymer is a value calculated from a theoretical value. It is calculated from the following formula (1). In the following formula (1), the expression “copolymerized amount of a monomer having a hydroxyl group” means a ratio (unit: % by mass) of the monomer having a hydroxyl group with respect to all monomers constituting a polymer.

$$\begin{matrix}[ Equation 1 ] & \\ Hydroxyl value = \frac{copolymerized amount of monomer having hydroxyl group}{molecular weihht of monomer having hydroxyl group} \times \frac{m o l e cular weight of KOH}{100} \times 100 & ( 1 )\end{matrix}$$

A glass transition temperature of a copolymer obtained by polymerizing a monomer mixture is Tg (theoretical value) calculated from the Fox equation of formula (2) below using a known glass transition temperature of a homopolymer of each monomer. For the glass transition temperature of homopolymer of a monomer, for example, the value described in Polymer Handbook Fourth edition (Wiley-Interscience, 2003) can be used.

In the following formula (2),
Tg represents a glass transition temperature of a copolymer (unit: K),
Tg₁ represents a glass transition temperature of a homopolymer of a monomer 1 (unit: K),
Tg₂ represents a glass transition temperature of a homopolymer of a monomer 2 (unit: K),
Tgₙ represents a glass transition temperature of a homopolymer of a monomer n (unit: K),
W₁ represents a weight fraction of the monomer 1 in a monomer mixture,
W₂ represents a weight fraction of the monomer 2 in the monomer mixture, and
Wₙ represents a weight fraction of the monomer n in the monomer mixture.

$$\begin{matrix}[ Equation 2 ] & \\ \frac{1}{T g} = \frac{{W}_{1}}{T {g}_{1}} + \frac{{W}_{2}}{T {g}_{2}} + … + \frac{{W}_{n}}{T {g}_{n}} & ( 2 )\end{matrix}$$

The viscosity of a conductive ink composition is a value measured with a rheometer. It is a measured value of viscosity at a shear rate of 5.1 (unit: 1/s). The temperature at which the viscosity is measured is 23° C. unless otherwise specified.

### FIRST EMBODIMENT

### <<Conductive Ink Composition>>

A conductive ink composition of a first embodiment (hereinafter also referred to as a “first composition”) contains a (meth)acrylic polymer (A) and silver particles (B).

In the present specification, the specific surface area of silver particles is a value measured by adsorbing a mixed gas of helium and nitrogen onto the silver particles and measuring the specific surface area of the silver particles from the amount of the adsorbed mixed gas (BET method).

In the present specification, the maximum particle diameter and 50% average particle diameter of silver particles are the maximum particle diameter and a median diameter of the 50% cumulative volume in a particle diameter distribution curve measured by means of laser diffraction particle diameter analysis.

### <(Meth)Acrylic Polymer (A)>

The (meth)acrylic polymer (A) is a polymer containing a unit based on a (meth)acrylate.

The content of the unit based on a (meth)acrylate is preferably 70% by mass or more, more preferably 80% by mass or more, still more preferably 90% by mass or more, and may be 100% by mass with respect to all units constituting the (meth)acrylic polymer (A).

The (meth)acrylic polymer (A) preferably contains one or more units (a1) based on a hydroxyl group-containing monomer. The unit (a1) contributes to the hydroxyl value of the (meth)acrylic polymer (A).

The unit (a1) is preferably a unit based on a (meth)acrylate having a hydroxyl group.

Specific examples of a hydroxyl group-containing monomer (a1) corresponding to the unit (a1) include 2-hydroxyethyl acrylate, 2-hydroxypropyl acrylate, 4-hydroxybutyl acrylate, and 2-hydroxyethyl methacrylate.

With respect to all units of the (meth)acrylic polymer (A), the content of the unit (a1) is preferably from 20 to 40% by mass, more preferably from 22 to 38% by mass, and still more preferably from 24 to 36% by mass. When the content of the unit (a1) is equal to or more than the lower limit value of the above range, a hydroxyl value of more than 50 mgKOH/g is likely to be obtained, and the affinity with silver particles is increased, resulting in excellent elasticity. When the content of the unit (a1) is equal to or less than the upper limit value, the self-cohesive force of the meth(acrylic) polymer is not too strong, and favorable dispersibility during ink production and favorable elasticity are likely to be obtained.

The (meth)acrylic polymer (A) preferably contains one or more units (a2) based on a (meth)acrylate having an alkyl group of 4 to 12 carbon atoms. The unit (a2) does not include the unit (a1).

The alkyl group having 4 to 12 carbon atoms in the unit (a2) may be linear or branched.

Specific examples of a (meth)acrylate (a2) corresponding to the unit (a2) include n-butyl (meth)acrylate, isobutyl (meth)acrylate, s-butyl (meth)acrylate, t-butyl (meth)acrylate and 2-ethylhexyl (meth)acrylate.

The content of the unit (a2) is preferably from 46 to 64% by mass, more preferably from 48 to 62% by mass, and still more preferably from 50 to 60% by mass, with respect to all units of the (meth)acrylic polymer (A). When the content of the unit (a2) is equal to or more than the lower limit value of the above range, favorable durability during expansion and contraction is likely to be obtained. When the content of the unit (a2) is equal to or less than the upper limit value, it is difficult to become rigid, and favorable elasticity is likely to be obtained.

The (meth)acrylic polymer (A) preferably contains one or more units (a3) based on a (meth)acrylate having an alkyl group of 1 to 3 carbon atoms. The unit (a3) does not include the unit (a1) or the unit (a2).

The alkyl group having 3 carbon atoms in the unit (a3) may be linear or branched.

Specific examples of a (meth)acrylate (a3) corresponding to the unit (a3) include methyl (meth)acrylate and ethyl (meth)acrylate.

The content of the unit (a3) is preferably from 6 to 19% by mass, more preferably from 8 to 17% by mass, and still more preferably from 10 to 15% by mass, with respect to all units of the (meth)acrylic polymer (A). When the content of the unit (a3) is equal to or more than the lower limit value of the above range, the flexibility is excellent, and sufficient elasticity is likely to be obtained. When the content of the unit (a3) is equal to or less than the upper limit value, the adhesion to the base material is excellent, and favorable durability during expansion and contraction is likely to be obtained.

The (meth)acrylic polymer (A) preferably contains one or more units (a4) based on a carboxy group-containing monomer. The unit (a4) does not include the unit (a1), the unit (a2), or the unit (a3).

Specific examples of a carboxy group-containing monomer (a4) corresponding to the unit (a4) include acrylic acid, methacrylic acid, itaconic acid, maleic acid, fumaric acid, crotonic acid, and an acid anhydride group-containing monomer (such as maleic anhydride and itaconic anhydride).

The content of the unit (a4) is preferably from 0.05 to 0.35% by mass, more preferably from 0.10 to 0.30% by mass, and still more preferably from 0.15 to 0.25% by mass, with respect to all units of the (meth)acrylic polymer (A). When the content of the unit (a4) is equal to or more than the lower limit value of the above range, the affinity with the silver particles is excellent, and sufficient elasticity is likely to be obtained. When the content of the unit (a4) is equal to or less than the upper limit value, the cohesive force of (meth)acrylic acid is not too high, and favorable elasticity is likely to be obtained.

The (meth)acrylic polymer (A) may contain, other than the above units (a1) to (a4), one or more units (a5) based on other monomers copolymerizable with the units (a1) to (a4).

Examples of other monomers (a5) corresponding to the unit (a5) include a (meth)acrylate having a linear or branched alkyl group of 13 to 20 carbon atoms, a (meth)acrylate having an aromatic ring, a (meth)acrylate having a non-aromatic cyclic hydrocarbon group, an epoxy group-containing (meth)acrylate, a vinyl ester-based monomer, a styrene-based monomer, an olefin-based monomer, a vinyl ether-based monomer, and a polyfunctional monomer.

For example, a vinyl ester-based monomer such as vinyl acetate and vinyl propionate is preferred.

The content of the unit (a5) is preferably 10% by mass or less, more preferably 5% by mass or less, still more preferably 2% by mass or less, and may be zero with respect to all units of the (meth)acrylic polymer (A).

The glass transition temperature of the (meth)acrylic polymer (A) is 0° C. or less, preferably less than −30° C., and more preferably less than −32° C. When the above glass transition temperature is equal to or lower than the upper limit value described above, drying properties during production of the conductive film can be ensured, and a favorable elongation rate can also be obtained. The lower limit of the above glass transition temperature is preferably higher than −50° C., and more preferably higher than −45° C. When the glass transition temperature of the (meth)acrylic polymer (A) is higher than −50° C., the conductive film exhibits excellent durability and is likely to have sufficient elasticity.

The weight average molecular weight of the (meth)acrylic polymer (A) is 500,000 or more, preferably 520,000 or more, and more preferably 540,000 or more. If the above weight average molecular weight is equal to or greater than the lower limit value described above, the stretch durability would be excellent. The upper limit of the above weight average molecular weight is preferably 990,000 or less, more preferably 950,000 or less, and still more preferably 900,000 or less from the viewpoint of ensuring flexibility and exhibiting electrical conductivity.

The hydroxyl value of the (meth)acrylic polymer (A) is higher than 50 mgKOH/g, preferably 75 mgKOH/g or higher, and more preferably 100 mgKOH/g or higher. When the above hydroxyl value exceeds 50 mgKOH/g, the affinity between the silver particles and the (meth)acrylic polymer is moderately high, and the elasticity is excellent. The upper limit of the above hydroxyl value is preferably 200 mgKOH/g or lower, more preferably 175 mgKOH/g or lower, and still more preferably 150 mgKOH/g or lower from the viewpoint of not inhibiting the electrical conductivity of the silver particles.

The (meth)acrylic polymer (A) may be produced by a conventional method, or a commercially available product may be used.

The (meth)acrylic polymer (A) may be used in the form of a (meth)acrylic polymer composition containing the (meth)acrylic polymer (A) and an optional solvent. The solid content of the (meth)acrylic polymer composition is not particularly limited, but from the viewpoint of handling during blending, it is desirable to have a viscosity that imparts appropriate fluidity. For example, it is preferably 50% by mass or less and 10% by mass or more, and more preferably 40% by mass or less and 20% by mass or more.

Examples of a preferred aspect of the (meth)acrylic polymer (A) include the following aspect (i).

[Aspect (i)]

A (meth)acrylic polymer in which
the content of the unit (a1) is from 20 to 40% by mass,
the content of the unit (a2) is from 46 to 64% by mass,
the content of the unit (a3) is from 6 to 19% by mass,
the content of the unit (a4) is from 0.05 to 0.35% by mass,
the content of the unit (a5) is 10% by mass or less,
the glass transition temperature is higher than −50° C. and lower than −30° C.,
the weight average molecular weight is from 500,000 to 990,000, and
the hydroxyl value is more than 50 mgKOH/g and equal to or less than 200 mgKOH/g.

It should be noted that the total of the units (a1) to (a5) does not exceed 100% by mass.

### <Silver Particles (B)>

The silver particles (B) have a specific surface area of 0.5 to 3.0 m²/g, a 50% average particle diameter of 0.5 to 14.0 pun, and a maximum particle diameter of 8 μm or more. The silver particles (B) preferably have a shape that is flat in one direction, such as a flake-like shape or a scale-like shape.

The above specific surface area is more preferably from 0.7 to 3.0 m²/g. The above 50% average particle diameter is more preferably from 1.0 to 12.0 am.

The surface of the silver particles (B) may be coated with an organic acid. Specific examples of the organic acid include stearic acid, oleic acid, lauric acid, and hexanoic acid. It should be noted that the organic acid is not limited to the above specific examples.

When the silver particles (B) that satisfy the above conditions are used, a conductive film with excellent electrical conductivity when stretched can be easily obtained. Further, by combining the (meth)acrylic polymer (A) and the silver particles (B) that satisfy the above conditions, a conductive film that hardly cracks or ruptures when stretched and can exhibit electrical conductivity even when highly stretched can be obtained.

### <Solvent (C)>

The first composition may contain one or more types of solvents (C) as necessary.

The solvent (C) is not particularly limited, and may be any one capable of uniformly dispersing the (meth)acrylic polymer (A) and the silver particles (B), having low volatility and stably maintaining the ink viscosity, and being removed in a drying step during conductive film formation.

Examples of the solvent (C) include ester-based solvents such as diethylene glycol monoethyl ether acetate (also known as ethyl carbitol acetate), hydrocarbon-based solvents such as decane, tetradecane, and cyclohexane, and alcohol-based solvents such as 2-ethylhexanol, 2-ethylhexyl ether derivatives, and diethylene glycol monobutyl ether.

### <Optional Components>

The first composition may contain an optional component other than the (meth)acrylic polymer (A), the silver particles (B), and the solvent (C) within a range that does not impair the effects of the present invention.

As the optional component, a component known in the field of conductive ink composition can be used.

For example, in order to improve printability, components that adjust the interfacial tension of the ink (for example, surfactants, leveling agents, and the like), components that adjust the viscosity of the ink (for example, thixotropic agents), and the like may be blended.

Further, for the purpose of improving adhesion to each base material, it is possible to blend a binder component different from the (meth)acrylic polymer (A). Examples of the binder component include polyurethane polymers, epoxy polymers, ester polymers, terpene resins, and terpene resin derivatives (for example, terpene phenolic resins and the like). The binder component can be blended in an amount that does not impair elasticity.

In addition, an ion scavenger can be blended for the purpose of preventing migration.

With respect to the total mass of the first composition, the solid content is from 50 to 80% by mass, preferably from 52 to 78% by mass, and more preferably from 54 to 76% by mass. When the solid content is within the above range, sufficient stretchability and favorable electrical conductivity when stretched are likely to be obtained. In addition, it is easy to obtain a viscosity suitable for printing. The solid content can be adjusted through the content of the solvent (C).

The viscosity of the first composition is preferably from 20 to 50 Pa-s, more preferably from 24 to 46 Pa-s, and still more preferably from 28 to 42 Pa-s. When the viscosity is within the above range, favorable printability is likely to be obtained. For example, properties suitable for screen printing are easily obtained.

For example, if the viscosity of the first composition is too high, clogging, rubbing, or the like may occur during printing, and if the viscosity is too low, printing failures such as bleeding or sagging may occur.

The content of the (meth)acrylic polymer (A) with respect to the solid content of the first composition is preferably from 3.0 to 10.5% by mass, more preferably from 4.0 to 10.0% by mass, and still more preferably from 4.5 to 9.5% by mass. When the content of the (meth)acrylic polymer (A) is equal to or more than the above lower limit value, sufficient elasticity is likely to be obtained. When the content of the (meth)acrylic polymer (A) is equal to or less than the above upper limit value, it is easy to ensure a sufficient content of the silver particles (B), and favorable electrical conductivity during expansion and contraction can be easily obtained.

The content of the silver particles (B) with respect to the solid content of the first composition is preferably from 80.0 to 97.0% by mass, more preferably from 85.0 to 96.5% by mass, and still more preferably from 90.0 to 96.0% by mass. When the content of the silver particles (B) is equal to or more than the above lower limit value, favorable electrical conductivity is likely to be obtained, and when the content of the silver particles (B) is equal to or less than the above upper limit value, it is easy to ensure a sufficient content of components other than the silver particles (B), and favorable properties such as elasticity are likely to be obtained.

The content of the optional component with respect to the solid content of the first composition is preferably 10% by mass or less, more preferably 5% by mass or less, and may be zero.

### <Method for Producing Conductive Ink Composition>

The first composition is obtained by uniformly mixing the (meth)acrylic polymer (A), the silver particles (B), the solvent (C), and an optional component as required.

As the (meth)acrylic polymer (A), a (meth)acrylic polymer composition containing the (meth)acrylic polymer (A) and a solvent compatible with the (meth)acrylic polymer (A) may be used. The solvent compatible with the (meth)acrylic polymer (A) may be a solvent mentioned above as an example of the solvent (C), or may be another good solvent (such as ethyl acetate).

A known method can be used as the mixing method. For example, the first composition can be produced by a method in which all the components are premixed using a stirrer, and the obtained premix is kneaded a plurality of times using a triple roll mill.

### <Conductive Film>

A conductive film is obtained by applying the first composition onto a base material or the like to form a coating film, and drying the coating film to remove the solvent (C).

The material and shape of the base material are not particularly limited. An elastic base material is preferred. Examples of the elastic material include polyurethane, ethylene propylene rubber, silicone rubber, and various elastomers.

A known coating method can be used as a method for applying the first composition onto the base material. Examples thereof include a printing method, a dipping method, a spray method, and a bar coating method. A printing method is preferred from the viewpoint of versatility and accuracy.

Examples of the printing method include an inkjet printing method, a flexographic printing method, a gravure printing method, a screen printing method, a pad printing method, and a lithography printing method. In particular, a screen printing method is preferred from the viewpoints that: the cost can be easily reduced; it is suitable for printing on a large area; and the thickness of the conductive film is easily increased.

The coating film may be heated in a drying step. The heating temperature during drying is preferably a temperature that does not adversely affect the base material and allows complete removal of the solvent in the coating material. Although it varies depending on the type of the base material, for example, the temperature is preferably from 80 to 150° C.

The thickness of the conductive film after drying is not particularly limited, but is preferably, for example, from 10 to 100 m, and more preferably from 20 to 80 m. When the thickness is equal to or more than the lower limit value of the above range, the electrical conductivity can be easily exhibited, and when the thickness is equal to or less than the upper limit value, the produced device can be made smaller in size.

The conductive film of the first embodiment is elastic and exhibits electrical conductivity, as shown in Examples described later. Adhesion to the base material is also favorable. Therefore, the first composition can be suitably used as a conductive material for forming wiring, electrodes, and the like on an elastic base material, and can provide favorable followability with respect to the expansion and contraction of the base material.

Further, the conductive film of the first embodiment also exhibits excellent resistance to cyclic stretching, as shown in Examples described later, and the stability of the electrical conductivity is favorable when repeatedly stretched.

According to the first embodiment, it is possible to realize a conductive film whose electrical conductivity can be detected even after 100 cycles of repeated stretching at an elongation rate of 100%, for example.

For example, it is possible to realize a conductive film having an absolute value of the difference in surface resistance value, before and after an operation (at the start and at the end) of 100 cycles of repeated stretching at an elongation rate of 100% (difference in surface resistance value before and after cyclic stretching), of 100Ω or less.

Further, the conductive film of the first embodiment exhibits electrical conductivity even in a stretched state, as shown in Examples described later.

For example, a wearable sensor requires an expansion and contraction of 200% when applied to the elbow, which is the maximum operating area of a person. According to the first embodiment, for example, it is possible to realize a conductive film whose electrical conductivity can be detected even in a stretched state at an elongation rate of 250%.

In addition, the conductive film of the first embodiment can maintain electrical conductivity in a stretched state even when it is repeatedly stretched as shown in Examples described later.

According to the first embodiment, for example, it is possible to realize a conductive film whose electrical conductivity can be detected in a stretched state at an elongation rate of 100% even when subjected to 100 cycles of repeated stretching at an elongation rate of 100%.

Further, according to the first embodiment, a conductive film whose electrical conductivity (resistance value) changes as the shape changes can be obtained.

More specifically, as shown in Examples described later, it is possible to realize a conductive film whose surface resistance value increases as the elongation rate increases. For example, it is possible to realize a conductive film having a logarithmic value of the amount of resistance change per 1% of elongation (unit: Q/%), when the elongation rate changes from 0% to 250%, of 5.0 or less, preferably 4.0 or less.

A conductive film whose resistance value changes as the shape changes as described above is suitable for use in a variable resistance sensor. More specifically, the conductive film of the first embodiment can be used as a resistor (sensing means) in a variable resistance sensor. Specific examples of the variable resistance sensor include a wearable sensor or flexible sensor that detects expansion and contraction by changes in electrical resistance, a strain sensor that measures the amount of strain by changes in electrical resistance, and a pressure-sensitive sensor capable of perceiving deformation and measuring the amount of deformation by changes in electrical resistance. Further, since it can exhibit high electrical conductivity even when expanded and contracted, it can also be used for conductive members (such as wiring, electrodes, antennas, and heating elements) that constitute elastic products. More specifically, use in conductive members (such as wiring, electrodes, and antennas) that constitute the above wearable sensor, the above pressure-sensitive sensor, a moving part of a robot, an artificial muscle, a flexible display or the like, wiring of an in-mold molded part, heating elements of a flexible heater, and the like can be mentioned.

For example, the conductive film of the first embodiment is suitable for use in electrodes that require elasticity in electronic devices, or for use in wiring that requires elasticity in electronic devices.

For example, the conductive film of the first embodiment is suitable for the detection part of a variable resistance sensor, the electrode of a variable resistance sensor, or the wiring of a variable resistance sensor.

### Second Embodiment

A conductive ink composition of a second embodiment (hereinafter also referred to as a “second composition”) contains a (meth)acrylic polymer (A) and carbon black (CB) (hereinafter also referred to as (CB) particles).

In the present specification, the specific surface area of carbon black is a value measured by adsorbing nitrogen onto carbon black particles and measuring the specific surface area of carbon black from the amount of adsorbed nitrogen (BET method). The BET specific surface area of carbon black is measured by a method in accordance with ASTM D 3037.

In the present specification, the diameter of an aggregate of primary particles of carbon black is a value measured by the method for measuring an aggregate diameter described in JIS K6217-6.

### <(Meth)Acrylic Polymer (A)>

As the (meth)acrylic polymer (A) in the second embodiment, the same polymer as the (meth)acrylic polymer (A) in the first embodiment can be used.

The (meth)acrylic polymer (A) in the second embodiment can contain the same units (a1) to (a4) as in the first embodiment, and may further contain a unit (a5).

In the second embodiment, with respect to all units of the (meth)acrylic polymer (A), the content of the unit (a1) is preferably from 20 to 40% by mass, more preferably from 22 to 38% by mass, and still more preferably from 24 to 36% by mass. When the content of the unit (a1) is equal to or more than the lower limit value of the above range, a hydroxyl value of more than 50 mgKOH/g is likely to be obtained, and the affinity with the (CB) particles is increased, resulting in excellent elasticity. When the content of the unit (a1) is equal to or less than the upper limit value, the self-cohesive force of the meth(acrylic) polymer is not too strong, and favorable dispersibility during ink production and favorable elasticity are likely to be obtained.

In the second embodiment, the content of the unit (a2) is preferably from 46 to 64% by mass, more preferably from 48 to 62% by mass, and still more preferably from 50 to 60% by mass, with respect to all units of the (meth)acrylic polymer (A). When the content of the unit (a2) is equal to or more than the lower limit value of the above range, favorable durability during expansion and contraction is likely to be obtained. When the content of the unit (a2) is equal to or less than the upper limit value, it is difficult to become rigid, and favorable elasticity is likely to be obtained.

In the second embodiment, the content of the unit (a3) is preferably from 6 to 19% by mass, more preferably from 8 to 17% by mass, and still more preferably from 10 to 15% by mass, with respect to all units of the (meth)acrylic polymer (A). When the content of the unit (a3) is equal to or more than the lower limit value of the above range, the flexibility is excellent, and sufficient elasticity is likely to be obtained. When the content of the unit (a3) is equal to or less than the upper limit value, the adhesion to the base material is excellent, and favorable durability during expansion and contraction is likely to be obtained.

In the second embodiment, the content of the unit (a4) is preferably from 0.05 to 0.35% by mass, more preferably from 0.10 to 0.30% by mass, and still more preferably from 0.15 to 0.25% by mass, with respect to all units of the (meth)acrylic polymer (A). When the content of the unit (a4) is equal to or more than the lower limit value of the above range, the affinity with the (CB) particles is excellent, and sufficient elasticity is likely to be obtained. When the content of the unit (a4) is equal to or less than the upper limit value, the cohesive force of (meth)acrylic acid is not too high, and favorable elasticity is likely to be obtained.

In the second embodiment, the content of the unit (a5) is preferably 10% by mass or less, more preferably 5% by mass or less, still more preferably 2% by mass or less, and may be zero with respect to all units of the (meth)acrylic polymer (A).

The glass transition temperature of the (meth)acrylic polymer (A) in the second embodiment is the same as that in the first embodiment.

The weight average molecular weight of the (meth)acrylic polymer (A) in the second embodiment is the same as that in the first embodiment.

In the second embodiment, the hydroxyl value of the (meth)acrylic polymer (A) is higher than 50 mgKOH/g, preferably 75 mgKOH/g or higher, and more preferably 100 mgKOH/g or higher. When the above hydroxyl value exceeds 50 mgKOH/g, the affinity between the (CB) particles and the (meth)acrylic polymer is moderately high, and the elasticity is excellent. The upper limit of the above hydroxyl value is preferably 200 mgKOH/g or lower, more preferably 175 mgKOH/g or lower, and still more preferably 150 mgKOH/g or lower from the viewpoint of not inhibiting the electrical conductivity of the (CB) particles.

In the second embodiment, the (meth)acrylic polymer (A) may be used in the form of a (meth)acrylic polymer composition containing the (meth)acrylic polymer (A) and an optional solvent. The solid content of the (meth)acrylic polymer composition is not particularly limited, but from the viewpoint of handling during blending, it is desirable to have a viscosity that imparts appropriate fluidity. For example, it is preferably 50% by mass or less and 10% by mass or more, and more preferably 40% by mass or less and 20% by mass or more.

Examples of a preferred aspect of the (meth)acrylic polymer (A) in the second embodiment include the above aspect (i).

### <Carbon Black (CB)>

The carbon black (CB) has a specific surface area of 50 m²/g or more and an aggregate diameter of 400 nm or less.

The above specific surface area is preferably from 50 to 1,300 m²/g, and more preferably from 55 to 1,000 m²/g.

The above aggregate diameter is preferably 400 nm or less from the viewpoint of not inhibiting the elasticity. The lower limit value of the above aggregate diameter is not particularly limited, but is preferably 100 nm or more, and more preferably 150 nm or more from the viewpoint of exhibiting electrical conductivity.

When the carbon black (CB) that satisfies the above conditions is used, a conductive film with excellent conductivity when stretched can be easily obtained. Further, by combining the (meth)acrylic polymer (A) and the carbon black (CB) that satisfies the above conditions, a conductive film that hardly cracks or ruptures when stretched can be obtained.

Examples of the carbon black (CB) include those commercially available as conductive carbon black. Specific examples thereof include furnace black, channel black, thermal black, and acetylene black. Furnace black is preferred in view of achieving a good balance between elasticity and electrical conductivity.

One type of carbon black (CB) may be used, or two or more types thereof may be used in combination.

### <Solvent (C)>

The second composition may contain one or more types of solvents (C) as necessary.

The solvent (C) is not particularly limited, and may be any one capable of uniformly dispersing the (meth)acrylic polymer (A) and the (CB) particles, having low volatility and stably maintaining the ink viscosity, and being removed in a drying step during conductive film formation.

As the solvent (C) in the second embodiment, the same compound as the solvent (C) in the first embodiment can be used.

### <Graphite Material (D)>

The second composition may contain one or more types of graphite materials (D) as a conductive auxiliary agent. The graphite material (D) contributes to improving electrical conductivity. Examples of the graphite material include expanded graphite, natural graphite (scaly graphite, flaky graphite), and artificial graphite.

The shape of the graphite material (D) is not particularly limited, but from the viewpoint of not inhibiting elasticity, it is preferably a shape that is flat in one direction, such as a flake-like shape or a scale-like shape, and the 50% average particle diameter is preferably from 10 μm to 30 μm. It should be noted that the 50% average particle diameter of the graphite material (D) is a median diameter of the 50% cumulative volume in a particle diameter distribution curve measured by means of laser diffraction particle diameter analysis.

### <Optional Components>

The second composition may contain an optional component other than the (meth)acrylic polymer (A), the carbon black (CB), the solvent (C), and the graphite material (D) within a range that does not impair the effects of the present invention.

As the optional component, a component known in the field of conductive ink composition can be used.

For example, in order to improve printability, components that adjust the interfacial tension of the ink (for example, surfactants, leveling agents, and the like), components that adjust the viscosity of the ink (for example, thixotropic agents), and the like may be blended.

Further, for the purpose of improving adhesion to each base material, it is possible to blend a binder component different from the (meth)acrylic polymer (A). Examples of the binder component include polyurethane polymers, epoxy polymers, ester polymers, terpene resins, and terpene resin derivatives (for example, terpene phenolic resins and the like). The binder component can be blended in an amount that does not impair elasticity.

With respect to the total mass of the second composition, the solid content is from 15 to 30% by mass, preferably from 16 to 29% by mass, and more preferably from 17 to 28% by mass. When the solid content is within the above range, sufficient stretchability and favorable electrical conductivity when stretched are likely to be obtained. In addition, it is easy to obtain a viscosity suitable for printing. The solid content can be adjusted through the content of the solvent (C).

The viscosity of the second composition is preferably from 20 to 100 Pa-s, more preferably from 22 to 98 Pa-s, and still more preferably from 24 to 96 Pa-s. When the viscosity is within the above range, favorable printability is likely to be obtained. For example, properties suitable for screen printing are easily obtained.

For example, if the viscosity of the second composition is too high, clogging, rubbing, or the like may occur during printing, and if the viscosity is too low, printing failures such as bleeding or sagging may occur.

The content of the (meth)acrylic polymer (A) with respect to the solid content of the second composition is preferably from 40 to 62% by mass, more preferably from 41 to 60% by mass, and still more preferably from 42 to 58% by mass. When the content of the (meth)acrylic polymer (A) is equal to or more than the above lower limit value, the adhesion to the base material is excellent. In addition, sufficient elasticity is likely to be obtained. When the content of the (meth)acrylic polymer (A) is equal to or less than the above upper limit value, it is easy to ensure a sufficient content of the (CB) particles, and favorable electrical conductivity during expansion and contraction can be easily obtained.

The content of the carbon black (CB) with respect to the solid content of the second composition is preferably from 18 to 50% by mass, more preferably from 20 to 48% by mass, and still more preferably from 22 to 46% by mass. When the content of the carbon black (CB) is equal to or more than the above lower limit value, favorable electrical conductivity is likely to be obtained. When the content of the carbon black (CB) is equal to or less than the above upper limit value, it is easy to ensure a sufficient content of components other than the (CB) particles, and favorable properties such as elasticity are likely to be obtained. In addition, the viscosity does not become too high, and printing defects such as rubbing are less likely to occur.

The content of the optional component with respect to the solid content of the second composition is preferably 30% by mass or less, more preferably 25% by mass or less, and may be zero.

When the second composition contains a graphite material (D), the content of the graphite material (D) is preferably from 16 to 30% by mass, more preferably from 18 to 28% by mass, and still more preferably from 20 to 26% by mass with respect to the solid content of the second composition. When the content of the graphite material (D) is equal to or more than the above lower limit value, the effect of improving electrical conductivity is excellent, and when the content of the graphite material (D) is equal to or less than the above upper limit value, the conductive film is less likely to become rigid, and favorable elasticity is likely to be obtained.

Further, when the second composition contains the graphite material (D), the ratio of the carbon black (CB) is preferably from 40 to 80% by mass, more preferably from 45 to 70% by mass, and still more preferably from 50 to 60% by mass with respect to the total mass of the carbon black (CB) and the graphite material (D). When the ratio of the carbon black (CB) is equal to or more than the above lower limit value, the conductive film is less likely to become rigid, and favorable elasticity is likely to be obtained. When the ratio of the carbon black (CB) is equal to or less than the above upper limit value, the effect of improving electrical conductivity by the graphite material (D) is likely to be obtained.

When the second composition contains other conductive carbon materials, the ratio of the other conductive carbon materials with respect to the total mass of the carbon black (CB), the graphite material (D), and the other conductive carbon materials is preferably 5% by mass or less, and more preferably 3% by mass or less.

### <Method for Producing Conductive Ink Composition>

The second composition is obtained by uniformly mixing the (meth)acrylic polymer (A), the carbon black (CB), the solvent (C), and the graphite material (D) and an optional component as required.

As the (meth)acrylic polymer (A), a (meth)acrylic polymer composition containing the (meth)acrylic polymer (A) and a solvent compatible with the (meth)acrylic polymer (A) may be used. The solvent compatible with the (meth)acrylic polymer (A) may be a solvent mentioned above as an example of the solvent (C), or may be another good solvent (such as ethyl acetate).

The same method as in the first embodiment can be used as a mixing method.

### <Conductive Film>

A conductive film is obtained by applying the second composition onto a base material or the like to form a coating film, and drying the coating film to remove the solvent (C).

The material and shape of the base material can be the same as those in the first embodiment.

As the method for applying the second composition onto the base material, the same method as that in the first embodiment can be used.

Similarly to the first embodiment, the coating film may be heated in a drying step.

The thickness of the conductive film after drying can be the same as that in the first embodiment.

The conductive film of the second embodiment is elastic and exhibits electrical conductivity, as shown in Examples described later. Adhesion to the base material is also favorable. Therefore, the second composition can be suitably used as a conductive material for forming wiring, electrodes, and the like on an elastic base material, and can provide favorable followability with respect to the expansion and contraction of the base material.

For example, when the detection limit of the surface resistance value is 1.0×10⁷ (Q) or less, it is possible to realize a conductive film whose elongation rate for which the surface resistance value can be measured is 300% or more, and preferably 350% or more.

Further, the conductive film of the second embodiment also exhibits excellent resistance to cyclic stretching, as shown in Examples described later, and the stability of the electrical conductivity is favorable when repeatedly stretched.

According to the second embodiment, it is possible to realize a conductive film whose electrical conductivity can be detected even after 100 cycles of repeated stretching at an elongation rate of 100%, for example.

For example, it is possible to realize a conductive film having an absolute value of the difference in surface resistance value, before and after an operation (at the start and at the end) of 100 cycles of repeated stretching at an elongation rate of 100% (difference in surface resistance value before and after cyclic stretching), of 5.0×10⁴Ω or less.

Further, the conductive film of the second embodiment exhibits electrical conductivity even in a stretched state, as shown in Examples described later.

For example, a wearable sensor requires an expansion and contraction of 200% when applied to the elbow, which is the maximum operating area of a person. According to the second embodiment, for example, it is possible to realize a conductive film whose electrical conductivity can be detected even in a stretched state at an elongation rate of 300%.

In addition, the conductive film of the second embodiment can maintain electrical conductivity in a stretched state even when it is repeatedly stretched as shown in Examples described later.

According to the second embodiment, for example, it is possible to realize a conductive film whose electrical conductivity can be detected in a stretched state at an elongation rate of 100% even when subjected to 100 cycles of repeated stretching at an elongation rate of 100%.

Further, according to the second embodiment, a conductive film whose electrical conductivity (resistance value) changes as the shape changes can be obtained.

More specifically, as shown in Examples described later, it is possible to realize a conductive film whose surface resistance value increases as the elongation rate increases. For example, it is possible to realize a conductive film having a logarithmic value of the amount of resistance change per 1% of elongation (unit: Q/%), when the elongation rate changes from 0% to 300%, of 5.0 or less, preferably 4.5 or less.

A conductive film whose resistance value changes as the shape changes as described above is suitable for use in a variable resistance sensor. More specifically, the conductive film of the second embodiment can be used as a resistor (sensing means) in a variable resistance sensor. Specific examples of the variable resistance sensor include a wearable sensor or flexible sensor that detects expansion and contraction by changes in electrical resistance, a strain sensor that measures the amount of strain by changes in electrical resistance, and a pressure-sensitive sensor capable of perceiving deformation and measuring the amount of deformation by changes in electrical resistance. Further, since it can exhibit high electrical conductivity even when expanded and contracted, although not as high as that of metallic ink using filler metals, it can also be used for conductive members (such as wiring, electrodes, and heaters) that constitute elastic products. More specifically, use in conductive members (wiring, electrodes, and the like) that constitute the above wearable sensor, the above pressure-sensitive sensor, or a biosensor (for example, a glucose sensor, and the like), heating elements of a flexible heater, and the like can be mentioned.

For example, the conductive film of the second embodiment is suitable for use in electrodes that require elasticity in electronic devices, or for use in wiring that requires elasticity in electronic devices.

For example, the conductive film of the second embodiment is suitable for the detection part of a variable resistance sensor, the electrode of a variable resistance sensor, or the wiring of a variable resistance sensor.

### EXAMPLES

Hereinafter, the present invention will be described in more detail with reference to Examples, but the present invention is not limited by the following description. In the following description, the unit “%” of the content is “% by mass” unless otherwise specified.

### <Production Example of (Meth)Acrylic Polymer Composition>

The monomers shown in Tables 1 and 7 are as follows.

[Hydroxyl Group-Containing Monomer (a1)]
2HPA: 2-hydroxypropyl acrylate
4HBA: 4-hydroxybutyl acrylate
2HEA: 2-hydroxyethyl acrylate
2HEMA: 2-hydroxyethyl methacrylate
   [C4-12 Alkyl (Meth)Acrylate (a2)]
BA: butyl acrylate
2EHA: 2-ethylhexyl acrylate
   [C1-3 Alkyl (Meth)Acrylate (a3)]
MA: methyl acrylate
MMA: methyl methacrylate
   [Carboxy Group-Containing Monomer (a4)]
AA: acrylic acid
   [Other Monomer (a5)]
Vac: vinyl acetate

### Production Example 1-1: Production of (Meth)Acrylic Polymer Composition (1-1)

A (meth)acrylic polymer was synthesized by polymerizing a monomer mixture shown in Table 1 in a polymerization solvent, and a solvent was further added thereto to adjust the solid content concentration to obtain a (meth)acrylic polymer composition.

More specifically, 29.8 parts by mass of 2HPA, 57.2 parts by mass of BA, 12.8 parts by mass of MA, and 0.2 parts by mass of AA as monomers, and 0.02 parts by mass of 2,2′-azobisisobutyronitrile as a polymerization initiator and 43 parts by mass of ethyl acetate as a polymerization solvent were placed in a separable flask. After nitrogen gas was introduced to remove oxygen in the polymerization system, the temperature was raised to 70° C., and the reaction was carried out for 8 hours to obtain a (meth)acrylic polymer A1-1. Ethyl acetate was added thereto to adjust the solid content concentration to 33% by mass to obtain a (meth)acrylic polymer composition (1-1).

The glass transition temperature, weight average molecular weight, and hydroxyl value of the (meth)acrylic polymer are shown in Table 1 (the same applies hereinafter).

### Production Examples 1-2 to 1-5: Production of (Meth)Acrylic Polymer Compositions (1-2) to (1-5)

The compositions of monomer mixtures were changed as shown in Table 1, and the monomer mixtures were polymerized in the same manner as in Production Example 1 to synthesize (meth)acrylic polymers A1-2 to A1-5. Ethyl acetate was added thereto to adjust the solid content concentrations as shown in Table 1 to obtain (meth)acrylic polymer compositions (1-2) to (1-5).

### (Comparative Composition (1-6))

A polyester resin solution (“Nichigo-Polyester LP-035” (product name) manufactured by Mitsubishi Chemical Corporation) was used as a comparative composition (1-6).

The glass transition temperature, weight average molecular weight, and hydroxyl value of the polyester resin (comparative resin P1-6) in the comparative composition (1-6) are shown in Table 1.

TABLE 1

| | | | Production | Production | Production | Production | Production |
|---|---|---|---|---|---|---|---|
| | | | Example | Example | Example | Example | Example |
| | | | 1-1 | 1-2 | 1-3 | 1-4 | 1-5 |
| Monomer | (a1) | 2HPA | 29.8 | 30.1 | — | — | — |
| mixture | | 4HBA | — | — | 0.1 | — | — |
| (parts by | | 2HEA | — | — | — | 0.4 | — |
| mass) | | 2HEMA | — | — | — | — | 13 |
| | (a2) | BA | 57.2 | 57.2 | 35.5 | 99.3 | — |
| | | 2EHA | — | — | 54.9 | — | 65.3 |
| | (a3) | MA | 12.8 | 12.5 | — | — | — |
| | | MMA | — | — | 0.9 | — | 16.3 |
| | (a4) | AA | 0.2 | 0.2 | 2.0 | 0.3 | 1.1 |
| | (a5) | Vac | — | — | 6.6 | — | 4.3 |

| | | | | | | | |
|---|---|---|---|---|---|---|---|
| | Total | 100 | 100 | 100 | 100 | 100 | |
| (Meth)acrylic | Glass transition | −36 | −36 | −57 | −55 | −36 | 20 |
| polymer (A) | temperature (° C.) | | | | | | |
| | Weight average | 700,000 | 600,000 | 300,000 | 1,000,000 | 350,000 | 16,000 |
| | molecular weight | | | | | | |
| | Hydroxyl value | 130 | 130 | 1 | 3 | 50 | 5 |
| | (mgKOH/g) | | | | | | |
| | Name of | A1-1 | A1-2 | A1-3 | A1-4 | A1-5 | Comparative |
| | (meth)acrylic | | | | | | resin P1-6 |
| | polymer | | | | | | |

| | | | | | | |
|---|---|---|---|---|---|---|
| Name of (meth)acrylic polymer | (1-1) | (1-2) | (1-3) | (1-4) | (1-5) | Comparative |
| composition | | | | | | composition |
| | | | | | | (1-6) |
| Solid content (%) of (meth)acrylic | 33 | 45 | 30 | 30 | 45 | 30 |
| polymer composition | | | | | | |

### <Silver Particles (B)>

The following silver particles were used. The shape, specific surface area, 50% average particle diameter, and maximum particle diameter of each silver particle are shown in Table 2.
Silver particles (B1): “Silbest TC-12” (product name) manufactured by Tokuriki Honten Co., Ltd., flaky particles.
Silver particles (B2): “AgC-2011” (product name) manufactured by Fukuda Metal Foil & Powder Co., Ltd., flaky particles.
Silver particles (B3): “Silbest TC-725” (product name) manufactured by Tokuriki Honten Co., Ltd., flaky particles.
Silver particles (B4): “SLO2” (product name) manufactured by Mitsui Mining & Smelting Co., Ltd., spherical particles.
Silver particles (B5): “M612” (product name) manufactured by Tokusen Kogyo Co., Ltd., flaky particles.

### <Solvent (C)>

The following solvents were used.
Solvent (C1-1): diethylene glycol monoethyl ether acetate
Solvent (C1-2): polyoxypropylene 2-ethylhexyl ether derivative (“Blaunon EHP-4” (product name) manufactured by Aoki Oil Industrial Co., Ltd.)

### <Optional Components>

The following optional components were used.
Optional component (1-1): binder, terpene phenolic resin (“YS Polyster T80” (product name) manufactured by Yasuhara Chemical Co., Ltd.)
Optional component (1-2): ion scavenger (Toagosei “IXEPLAS-A2” (product name) manufactured by Toagosei Co., Ltd.)

TABLE 2

| | | Specific | 50% average | |
|---|---|---|---|---|
| | | surface area | particle diameter | Maximum |
| | | (m²/g) | (μm) | particle diameter |
| Silver | B1 | 1.2 to 2.5 | 1.5 to 3.5 | 8 μm or more |
| particles | B2 | 1.5 to 2.3 | 1.5 to 3.5 | 8 μm or more |
| (B) | B3 | 2.0 to 4.0 | 0.5 to 1.5 | Less than 8 μm |
| | B4 | 2.1 | 0.29 | Less than 8 μm |
| | B5 | 0.8 to 1.2 | 6.0 to 12.0 | 8 μm or more |

### Examples 1-1 to 1-8, Comparative Examples 1-1 to 1-8

Silver particles and a solvent were blended into a (meth)acrylic polymer composition according to the proportions shown in Tables 3 to 6. In Example 1-5, the optional component (1-1), silver particles, and a solvent were blended into a (meth)acrylic polymer composition. In Comparative Example 1-4, silver particles and a solvent were blended into the comparative composition (1-6).

After premixing all the formulation ingredients using a stirrer, the resulting mixture was kneaded using a triple roll mill (“BR-150VIII” (product name), manufactured by Imex Co., Ltd.) to obtain a conductive ink composition. The kneading was performed under conditions in which a treatment was carried out twice at a rotational frequency of 120 rpm and a distance between the rolls of 40 μm, and then a treatment was further carried out twice after reducing the distance between the rolls to 10 μm.

The solid content, the content of the (meth)acrylic polymer (A), and the content of the silver particles (B) with respect to the total mass of the conductive ink composition of each example are shown in the table. Further, the content of the (meth)acrylic polymer (A) and the content of the silver particles (B) with respect to the solid content are shown in the table. The viscosity of the conductive ink composition is shown in the table.

It should be noted that a blank column in the table means that the formulation ingredient is not blended.

### <<Evaluation Method>>

The obtained conductive film was evaluated using the following method.

The conductive ink composition obtained in each example was applied onto a base material and dried at 130° C. for 10 minutes to produce a laminate having a conductive film on the base material. An elastic polyurethane sheet (thickness: 100 μm) was used as the base material. The dry film thickness of the conductive film was set to approximately 30 μm.

The following properties were evaluated for the obtained conductive film. The results are shown in Tables 3 to 6.

### (Measurement of Volume Resistivity)

Using the laminate obtained in each example as a sample, the volume resistance value (unit: Ω·cm) of the conductive film was measured using a four-terminal electrode of a resistivity meter (“Loresta” (product name) manufactured by Nittoseiko Analytech Co., Ltd.). The thickness of the conductive film was measured using a microgauge.

### (Evaluation of Adhesion)

Using the laminate obtained in each example as a sample, a peel test was conducted using a cross-cut method based on JIS: K5600-5-6. More specifically, the conductive film of the laminate was cross-cut using a cutter knife so that 100 squares each having a side of 1 mm were formed on the conductive film. Cellotape (registered trademark) was attached to this conductive film and peeled off in the vertical direction, and the degree of peeling of the conductive film was evaluated using the following criteria.

The case where all 100 squares were not peeled off was evaluated as “A”, the case where 1 to 99 squares were peeled off was evaluated as “B”, and the case where all 100 squares were peeled off was evaluated as “C”.

### (Stretching Test)

A sample was prepared by cutting the laminate obtained in each example into a No. 3 dumbbell shape, and the sample was set in a tensile testing machine. The distance between the marked lines (initial dimension) was set to 20 mm, the sample was stretched under a condition of 23° C. at a tensile speed of 10 mm/min, and the surface resistance value (unit: Q) between the marked lines was measured using a tester (“CDM-2000D” (product name) manufactured by Custom Corporation) at each specific elongation rate.

The elongation rate is a value calculated using the following calculation formula.

$$Elongation rate ( \% ) = ( ( distance between marked lines after elongation ( mm ) ) - ( initial dimension ) ) / ( initial dimension ) \times 100$$

The table shows a surface resistance value R¹ when the elongation rate is 200% (at 200% elongation), that is, when the distance between the marked lines is 60 mm.

The table also shows a surface resistance value R² when the elongation rate is 250% (at 250% elongation), that is, when the distance between the marked lines is 70 mm.

In addition, the table shows a logarithmic value of the amount of resistance change per 1% of elongation (unit: Q/%) when the elongation rate changes from 0% to 250%, which is calculated using the following formula (3). R⁰ in the formula (3) indicates a surface resistance value when the elongation rate is 0% (at 0% elongation).

The case where a crack or rupture occurred in the film when stretched is indicated as “B (not achieved)”, and the case where the film could be elongated but the electrical conductivity could not be detected is indicated as “B (unmeasurable)”.

$$\begin{matrix}[ Equation 3 ] & \\ Logarithmic value of amount of resistance change per 1 \% of elongation = {Log}_{10} \times \frac{( {R}^{2} - {R}^{0} )}{250} & ( 3 )\end{matrix}$$

### (Cyclic Stretching Test)

A sample was prepared by cutting the laminate obtained in each example into a No. 3 dumbbell shape, and the sample was set in a tensile testing machine. The distance between the marked lines (initial dimension) was set to 20 mm, and cyclic stretching was carried out under conditions at a temperature of 23° C. and a tensile speed of 500 mm/min.

More specifically, an operation of stretching from the initial dimension at the start (0%, distance between marked lines: 20 mm) to an elongation rate of 100% (distance between marked lines: 40 mm), followed by returning to an elongation rate of 0% (distance between marked lines: 20 mm) was defined as a first cycle; then an operation of stretching from the elongation rate of 0% to an elongation rate of 100%, followed by returning to an elongation rate of 0% was defined as a second cycle; and the operation was carried out until the 100th cycle. The surface resistance value (unit: Q) between the marked lines was measured every 10 cycles using the resistivity meter described above.

The table shows the surface resistance value at the start (0%), the surface resistance value when stretched by 100% in the first cycle, the surface resistance value when stretched by 100% in the 100th cycle, and the surface resistance value when the elongation rate was returned to 0% after the 100th stretching (0% at the end).

In addition, the difference in surface resistance value before and after the cyclic stretching test was evaluated. The difference between the surface resistance value at the end (0% elongation) and the surface resistance value at the start (0% elongation) is shown in the table as an absolute value.

The case where a crack or rupture occurred in the film when stretched in the first stretching or the 100th stretching is indicated as “B (not achieved)”.

TABLE 3

| | | | Ex. 1-1 | Ex. 1-2 | Ex. 1-3 | Ex. 1-4 |
|---|---|---|---|---|---|---|
| Proportion of | (Meth)acrylic | (1-1) | 15 | 10 | 15 | |
| conductive ink | polymer | (1-2) | | | | 10 |
| composition | composition | (1-3) | | | | |
| (% by mass) | | (1-4) | | | | |
| | | (1-5) | | | | |
| | Comparative composition (1-6) | | | | | |
| | Silver | B1 | 50 | 70 | | 50 |
| | particles (B) | B2 | | | 50 | |
| | | B3 | | | | |
| | | B4 | | | | |
| | | B5 | | | | |
| | Solvent (C) | C1-1 | 35 | 20 | 35 | 40 |
| | | C1-2 | | | | |
| | Optional | Optional | | | | |
| | component | component 1-1 | | | | |
| | | Optional | | | | |
| | | component 1-2 | | | | |
| | Total | | 100 | 100 | 100 | 100 |
| Solid content (% by mass) | | | 54.95 | 73.3 | 54.95 | 54.5 |
| Content of (meth)acrylic polymer (A) (% by mass) | | | 4.95 | 3.3 | 4.95 | 4.5 |
| Content of silver particles (B) (% by mass) | | | 50 | 70 | 50 | 50 |
| (Meth)acrylic polymer (A) / solid content (% by mass) | | | 9.01 | 4.50 | 9.01 | 8.26 |
| Silver particles (B) / solid content (% by mass) | | | 90.99 | 95.50 | 90.99 | 91.74 |
| Viscosity (Pa · s) | | | 28 | 40 | 30 | 23 |
| Evaluation of | Volume resistivity (Ω · cm) | | 6.0 × 10⁻⁵ | 1.3 × 10⁻⁵ | 4.8 × 10⁻⁵ | 5.6 × 10⁻⁵ |
| conductive | Adhesion | | A | A | A | A |
| film | Surface resistance value | | 11 | 8.9 × 10⁻¹ | 8.6 | 24 |
| | R⁰ (Ω) at 0% elongation | | | | | |
| | Surface resistance value | | 1.5 × 10³ | 7.8 × 10² | 8.9 × 10² | 2.0 × 10³ |
| | R¹ (Ω) at 200% elongation | | | | | |
| | Surface resistance value | | 2.2 × 10⁴ | 8.2 × 10³ | 1.5 × 10⁴ | 5.8 × 10⁴ |
| | R² (Ω) at 250% elongation | | | | | |
| | Logarithmic value of amount | | 2.9 | 1.5 | 1.8 | 3.4 |
| | of resistance value change | | | | | |
| | (Ω/%) from 0 to 250% | | | | | |
| | Surface resistance | At the start (0%) | 11 | 8.9 × 10⁻¹ | 8.6 | 24 |
| | value (Ω) during | At the end (0%) | 29 | 15 | 22 | 88 |
| | cyclic stretching | Difference in | 18 | 14 | 13 | 64 |
| | | surface | | | | |
| | | resistance value | | | | |
| | | before and after | | | | |
| | | cyclic stretching | | | | |
| | | 1^{st} cycle: at | 1.5 × 10² | 7.8 × 10¹ | 8.2 × 10¹ | 1.3 × 10² |
| | | 100% elongation | | | | |
| | | 100^{th} cycle: at | 4.2 × 10³ | 2.1 × 10³ | 1.5 × 10³ | 6.7 × 10³ |
| | | 100% elongation | | | | |

TABLE 4

| | | | Ex. 1-5 | Ex. 1-6 | Ex. 1-7 | Ex. 1-8 |
|---|---|---|---|---|---|---|
| Proportion of | (Meth)acrylic | (1-1) | 15 | 10 | 10 | 15 |
| conductive ink | polymer | (1-2) | | | | |
| composition | composition | (1-3) | | | | |
| (% by mass) | | (1-4) | | | | |
| | | (1-5) | | | | |
| | Comparative composition (1-6) | | | | | |
| | Silver | B1 | 60 | | 53 | 40 |
| | particles (B) | B2 | | | | |
| | | B3 | | | | |
| | | B4 | | | | |
| | | B5 | | 70 | 17 | 18 |
| | Solvent (C) | C1-1 | 10 | 20 | 20 | 20 |
| | | C1-2 | 10 | | | |
| | Optional | Optional | 5 | | | |
| | component | component 1-1 | | | | |
| | | Optional | | | | 2 |
| | | component 1-2 | | | | |
| | Total | | 100 | 100 | 100 | 100 |
| Solid content (% by mass) | | | 69.95 | 73.3 | 73.3 | 64.95 |
| Content of (meth)acrylic polymer (A) (% by mass) | | | 4.95 | 3.3 | 3.3 | 4.95 |
| Content of silver particles (B) (% by mass) | | | 60 | 70 | 70 | 58 |
| (Meth)acrylic polymer (A) / solid content (% by mass) | | | 7.08 | 4.50 | 4.50 | 7.62 |
| Silver particles (B) / solid content (% by mass) | | | 85.78 | 95.50 | 95.50 | 89.29 |
| Viscosity (Pa · s) | | | 39 | 31 | 36 | 41 |
| Evaluation of | Volume resistivity (Ω · cm) | | 2.3 × 10⁻⁵ | 9.3 × 10⁻⁶ | 7.8 × 10⁻⁶ | 9.5 × 10⁻⁵ |
| conductive | Adhesion | | A | A | A | A |
| film | Surface resistance value | | 1.2 | 7.5 × 10⁻¹ | 5.5 × 10⁻¹ | 8.0 × 10⁻¹ |
| | R⁰ (Ω) at 0% elongation | | | | | |
| | Surface resistance value | | 8.2 × 10² | 8.9 × 10² | 8.3 × 10² | 7.6 × 10² |
| | R¹ (Ω) at 200% elongation | | | | | |
| | Surface resistance value | | 9.8 × 10³ | 1.7 × 10⁴ | 1.4 × 10⁴ | 7.8 × 10³ |
| | R² (Ω) at 250% elongation | | | | | |
| | Logarithmic value of amount | | 1.6 | 1.8 | 1.8 | 1.5 |
| | of resistance value change | | | | | |
| | (Ω/%) from 0 to 250% | | | | | |
| | Surface resistance | At the start (0%) | 1.2 | 7.5 × 10⁻¹ | 5.5 × 10⁻¹ | 8.0 × 10⁻¹ |
| | value (Ω) during | At the end (0%) | 20 | 21 | 19 | 19 |
| | cyclic stretching | Difference in | 19 | 20 | 18 | 18 |
| | | surface | | | | |
| | | resistance value | | | | |
| | | before and after | | | | |
| | | cyclic stretching | | | | |
| | | 1^{st} cycle: at | 8.9 × 10¹ | 9.4 × 10¹ | 8.9 × 10¹ | 9.7 × 10¹ |
| | | 100% elongation | | | | |
| | | 100^{th} cycle: at | 3.7 × 10³ | 7.7 × 10³ | 4.5 × 10³ | 3.2 × 10³ |
| | | 100% elongation | | | | |

TABLE 5

| | | | Comp. | Comp. | Comp. | Comp. |
|---|---|---|---|---|---|---|
| | | | Ex. 1-1 | Ex. 1-2 | Ex. 1-3 | Ex. 1-4 |
| Proportion of | (Meth)acrylic | (1-1) | | | | |
| conductive ink | polymer | (1-2) | | | | |
| composition | composition | (1-3) | 15 | | | |
| (% by mass) | | (1-4) | | 15 | | |
| | | (1-5) | | | 10 | |
| | Comparative composition (1-6) | | | | | 15 |
| | Silver | B1 | 50 | 50 | 50 | 50 |
| | particles (B) | B2 | | | | |
| | | B3 | | | | |
| | | B4 | | | | |
| | | B5 | | | | |
| | Solvent (C) | C1-1 | 35 | 35 | 40 | 35 |
| | | C1-2 | | | | |
| | Optional | Optional | | | | |
| | component | component 1-1 | | | | |
| | | Optional | | | | |
| | | component 1-2 | | | | |
| | Total | | 100 | 100 | 100 | 100 |
| Solid content (% by mass) | | | 54.5 | 54.5 | 54.5 | 54.5 |
| Content of (meth)acrylic polymer (A) (% by mass) | | | 4.5 | 4.5 | 4.5 | 4.5 |
| | | | | | | Comparative |
| | | | | | | resin |
| Content of silver particles (B) (% by mass) | | | 50 | 50 | 50 | 50 |
| (Meth)acrylic polymer (A) / solid content (% by mass) | | | 8.26 | 8.26 | 8.26 | 8.26 |
| Silver particles (B) / solid content (% by mass) | | | 91.74 | 91.74 | 91.74 | 91.74 |
| Viscosity (Pa · s) | | | 16 | 37 | 21 | 10 |
| Evaluation of | Volume resistivity (Ω · cm) | | 6.9 × 10⁻⁵ | 5.3 × 10⁻⁵ | 4.8 × 10⁻⁵ | 2.3 × 10⁻⁵ |
| conductive | Adhesion | | B | C | C | C |
| film | Surface resistance value | | 66 | 41 | 22 | 8.6 |
| | R⁰ (Ω) at 0% elongation | | | | | |
| | Surface resistance value | | B (not | B (not | B (not | B (not |
| | R¹ (Ω) at 200% elongation | | achieved) | achieved) | achieved) | achieved) |
| | Surface resistance value | | B (not | B (not | B (not | B (not |
| | R² (Ω) at 250% elongation | | achieved) | achieved) | achieved) | achieved) |
| | Logarithmic value of amount | | — | — | — | — |
| | of resistance value change | | | | | |
| | (Ω/%) from 0 to 250% | | | | | |
| | Surface resistance | At the start (0%) | 66 | 41 | 22 | 8.6 |
| | value (Ω) during | At the end (0%) | B (not | B (not | B (not | B (not |
| | cyclic stretching | | achieved) | achieved) | achieved) | achieved) |
| | | Difference in | — | — | — | — |
| | | surface | | | | |
| | | resistance value | | | | |
| | | before and after | | | | |
| | | cyclic stretching | | | | |
| | | 1^{st} cycle: at | 4.5 × 10² | 9.8 × 10² | 3.7 × 10³ | 7.3 × 10⁴ |
| | | 100% elongation | | | | |
| | | 100^{th} cycle: at | B (not | B (not | B (not | B (not |
| | | 100% elongation | achieved) | achieved) | achieved) | achieved) |

TABLE 6

| | | | Comp. | Comp. | Comp. | Comp. |
|---|---|---|---|---|---|---|
| | | | Ex. 1-5 | Ex. 1-6 | Ex. 1-7 | Ex. 1-8 |
| Proportion of | (Meth)acrylic | (1-1) | 15 | 15 | 20 | 10 |
| conductive ink | polymer | (1-2) | | | | |
| composition | composition | (1-3) | | | | |
| (% by mass) | | (1-4) | | | | |
| | | (1-5) | | | | |
| | Comparative composition (1-6) | | | | | |
| | Silver | B1 | | | 35 | 80 |
| | particles (B) | B2 | | | | |
| | | B3 | 50 | | | |
| | | B4 | | 50 | | |
| | | B5 | | | | |
| | Solvent (C) | C1-1 | 35 | 35 | 45 | 10 |
| | | C1-2 | | | | |
| | Optional | Optional | | | | |
| | component | component 1-1 | | | | |
| | | Optional | | | | |
| | | component 1-2 | | | | |
| | Total | | 100 | 100 | 100 | 100 |
| Solid content (% by mass) | | | 54.95 | 54.95 | 41.6 | 83.3 |
| Content of (meth)acrylic polymer (A) (% by mass) | | | 4.95 | 4.95 | 6.6 | 3.3 |
| Content of silver particles (B) (% by mass) | | | 50 | 50 | 35 | 80 |
| (Meth)acrylic polymer (A) / solid content (% by mass) | | | 9.01 | 9.01 | 15.87 | 3.96 |
| Silver particles (B) / solid content (% by mass) | | | 90.99 | 90.99 | 84.13 | 96.04 |
| Viscosity (Pa · s) | | | 22 | 30 | 17 | 68 |
| Evaluation of | Volume resistivity (Ω · cm) | | 3.3 × 10⁻⁵ | 1.2 × 10⁻⁴ | 6.8 × 10⁻⁴ | 1.2 × 10⁻⁵ |
| conductive | Adhesion | | A | B | A | C |
| film | Surface resistance value | | 35 | 78 | 240 | 7.5 × 10⁻¹ |
| | R⁰ (Ω) at 0% elongation | | | | | |
| | Surface resistance value | | B (not | B (not | B | B (not |
| | R¹ (Ω) at 200% elongation | | achieved) | achieved) | (unmeasurable) | achieved) |
| | Surface resistance value | | B (not | B (not | B | B (not |
| | R² (Ω) at 250% elongation | | achieved) | achieved) | (unmeasurable) | achieved) |
| | Logarithmic value of amount of resistance | | — | — | — | — |
| | value change (Ω/%) from 0 to 250% | | | | | |
| | Surface resistance | At the start (0%) | 35 | 78 | 240 | 7.5 × 10⁻¹ |
| | value (Ω) during | At the end (0%) | B (not | B (not | B (not | B (not |
| | cyclic stretching | | achieved) | achieved) | achieved) | achieved) |
| | | Difference in | — | — | — | — |
| | | surface | | | | |
| | | resistance value | | | | |
| | | before and after | | | | |
| | | cyclic stretching | | | | |
| | | 1^{st} cycle: at | 6.9 × 10² | 1.5 × 10³ | 7.6 × 10³ | B (not |
| | | 100% elongation | | | | achieved) |
| | | 100^{th} cycle: at | 1.5 × 10⁴ | B (not | B | B (not |
| | | 100% elongation | | achieved) | (unmeasurable) | achieved) |

As shown in Tables 3 and 4, the conductive films of Examples 1-1 to 1-8 exhibited excellent electrical conductivity and adhesion to the base material, were elastic and exhibited excellent electrical conductivity when stretched, and the electrical conductivity could be detected even at 250% elongation.

The conductive films of Examples 1-1 to 1-8 also exhibited excellent resistance to cyclic stretching, and the electrical conductivity could be detected both in a stretched state (100%) and in a non-stretched state (0%) even after 100 cycles of repeated stretching at an elongation rate of 100%. Furthermore, the electrical conductivity was excellent in stability when repeatedly stretched, and the difference in surface resistance value before and after the cyclic stretching test was small.

Further, in Examples 1-1 to 1-8, it was observed that the surface resistance value tended to increase as the elongation rate increased.

On the other hand, as shown in Tables 5 and 6, in Comparative Examples 1-1 to 1-3 in which the glass transition temperature, weight average molecular weight, or hydroxyl value of the (meth)acrylic polymer (A) was outside the range of the present invention, and in Comparative Example 1-4 in which a comparative resin (polyester) was used in place of the (meth)acrylic polymer (A), a crack or rupture occurred in the film when stretched in the stretching test and the cyclic stretching test.

In Comparative Example 1-5 in which the maximum particle diameter of the silver particles was too small, a crack or rupture occurred in the film during the stretching test, and the surface resistance value could not be detected at an elongation of 200% or more.

In Comparative Example 1-6 in which the 50% average particle diameter and maximum particle diameter of the silver particles were too small, a crack or rupture occurred in the film during the stretching test and the cyclic stretching test.

In Comparative Example 1-7 in which the solid content of the conductive ink composition was too low, it was possible to elongate the conductive film by up to 250% in the stretching test, but the surface resistance value could not be detected. Also in the cyclic stretching test, it was possible to withstand a repeated elongation of 100%×100 cycles, but no surface resistance value could be detected.

In Comparative Example 1-8 in which the solid content of the conductive ink composition was too high, a crack or rupture occurred in the film during the stretching test and the cyclic stretching test.

### Production Example 2-1: Production of (Meth)Acrylic Polymer Composition (2-1)

A (meth)acrylic polymer was synthesized by polymerizing a monomer mixture shown in Table 7 in a polymerization solvent, and a solvent was further added thereto to adjust the solid content concentration to obtain a (meth)acrylic polymer composition.

More specifically, 29.8 parts by mass of 2HPA, 57.2 parts by mass of BA, 12.8 parts by mass of MA, and 0.2 parts by mass of AA as monomers, and 0.02 parts by mass of 2,2′-azobisisobutyronitrile as a polymerization initiator and 43 parts by mass of ethyl acetate as a polymerization solvent were placed in a separable flask. After nitrogen gas was introduced to remove oxygen in the polymerization system, the temperature was raised to 70° C., and the reaction was carried out for 8 hours to obtain a (meth)acrylic polymer A2-1. Ethyl acetate was added thereto to adjust the solid content concentration to 33% by mass to obtain a (meth)acrylic polymer composition (2-1).

The glass transition temperature, weight average molecular weight, and hydroxyl value of the (meth)acrylic polymer are shown in Table 7 (the same applies hereinafter).

### Production Examples 2-2 and 2-3: Production of (Meth)Acrylic Polymer Compositions (2-2) and (2-3)

The compositions of monomer mixtures were changed as shown in Table 7, and the monomer mixtures were polymerized in the same manner as in Production Example 2-1 to synthesize (meth)acrylic polymers A2-2 and A2-3. Ethyl acetate was added thereto to adjust the solid content concentrations as shown in Table 7 to obtain (meth)acrylic polymer compositions (2-2) and (2-3).

### (Comparative Composition (2-4))

A polyester resin solution (“Nichigo-Polyester LP-035” (product name) manufactured by Mitsubishi Chemical Corporation) was used as a comparative composition (2-4).

The glass transition temperature, weight average molecular weight, and hydroxyl value of the polyester resin (comparative resin P2-4) in the comparative composition (2-4) are shown in Table 7.

### [Table 7]

TABLE 7

| | | | Production | Production | Production | |
|---|---|---|---|---|---|---|
| | | | Example 2-1 | Example 2-2 | Example 2-3 | [symbol] |
| Monomer | (a1) | 2HPA | 29.8 | — | — | [symbol] |
| mixture (parts | | 4HBA | — | 0.1 | — | [symbol] |
| by mass) | | 2IIEMA | — | — | 13 | [symbol] |
| | (a2) | BA | 57.2 | 35.5 | — | [symbol] |
| | | 2EIIA | — | 54.9 | 65.3 | [symbol] |
| | (a3) | MA | 12.8 | — | — | [symbol] |
| | | MMA | — | 0.9 | 16.3 | [symbol] |
| | (a4) | AA | 0.2 | 2.0 | 1.1 | [symbol] |
| | (a5) | Vac | — | 6.6 | 4.3 | [symbol] |

| | | | | | |
|---|---|---|---|---|---|
| | Total | 100 | 100 | 100 | [symbol] |
| (Meth)acrylic | Glass transition | −36 | −57 | −36 | 20 |
| polymer (A) | temperature (° C.) | | | | |
| | Weight average molecular | 700,000 | 300,000 | 350,000 | 16,000 |
| | weight | | | | |
| | Hydroxyl value | 130 | 1 | 50 | 5 |
| | (mgKOH/g) | | | | |
| | Name of (meth)acrylic | A2-1 | A2-2 | A2-3 | Comparative |
| | polymer | | | | resin P2-4 |

| Name of (meth)acrylic polymer composition | (2-1) | (2-2) | (2-3) | Comparative |
|---|---|---|---|---|
| | | | | composition |
| | | | | (2-4) |
| Solid content (%) of (meth)acrylic polymer | 33 | 30 | 45 | 30 |
| composition | | | | |

[symbol]

indicates data missing or illegible when filed

### <Carbon Black (CB)>

The following (CB) particles were used. Table 8 shows the specific surface area and aggregate diameter of each (CB) particle.
Carbon black (CB1): “Ketjen Black EC300J” (product name) manufactured by Lion Specialty Chemicals Co., Ltd., furnace black.
Carbon black (CB2): “Ensaco 250G” (product name) manufactured by Imerys S.A., furnace black.
Carbon black (CB3): “Denka Black HS-100” (product name) manufactured by Denka Co., Ltd., acetylene black.

The following raw materials were used.

### <Solvent (C)>

Solvent (C2-1): diethylene glycol monoethyl ether acetate.

### <Graphite Material (D)>

Graphite (D2-1): “BSP-20A” (product name) manufactured by Shin-Etsu Kasei Kogyo Co., Ltd., expanded graphite, flaky form, average particle diameter: 20 m.

### <Dispersant (E)>

Dispersant (E2-1): “DA-1200” (product name) manufactured by Kusumoto Chemicals, Ltd., high molecular weight unsaturated polycarboxylic acid.

TABLE 8

| | | Specific surface area (m²/g) | Aggregate diameter (nm) |
|---|---|---|---|
| Carbon | CB1 | 780 | 300 |
| black | CB2 | 61 | 280 |
| (CB) | CB3 | 38 | 580 |

### Examples 2-1 to 2-5, Comparative Examples 2-1 to 2-7

Carbon black, a graphite material, a dispersant, and a solvent were blended into a (meth)acrylic polymer composition according to the proportions shown in Tables 9 to 11. In Comparative Examples 2-3 and 2-4, carbon black, a graphite material, a dispersant, and a solvent were blended into the comparative composition (2-4).

After premixing all the formulation ingredients using a stirrer, the resulting mixture was kneaded using a triple roll mill (“BR-150VIII” (product name), manufactured by Imex Co., Ltd.) to obtain a conductive ink composition. The kneading was performed under conditions in which a treatment was carried out twice at a rotational frequency of 120 rpm and a distance between the rolls of 40 μm, and then a treatment was further carried out twice after reducing the distance between the rolls to 10 μm.

The solid content, the content of the (meth)acrylic polymer (A), and the content of the carbon black (CB) with respect to the total mass of the conductive ink composition of each example are shown in the table. Further, the content of the (meth)acrylic polymer (A), the content of the carbon black (CB), and the content of the graphite material (D) with respect to the solid content are shown in the table. The viscosity of the conductive ink composition is shown in the table.

It should be noted that a blank column in the table means that the formulation ingredient is not blended.

### <<Evaluation Method>>

The obtained conductive film was evaluated using the following method.

The conductive ink composition obtained in each example was applied onto a base material and dried at 130° C. for 10 minutes to produce a laminate having a conductive film on the base material. An elastic polyurethane sheet (thickness: 100 μm) was used as the base material. The dry film thickness of the conductive film was set to approximately 30 μm.

The following properties were evaluated for the obtained conductive film. The results are shown in Tables 9 to 11.

### (Measurement of Volume Resistivity)

The volume resistivity was measured in the same manner as in Example 1-1 described above.

### (Evaluation of Adhesion)

The adhesion was evaluated in the same manner as in Example 1-1 described above.

### (Stretching Test (1))

A sample was prepared by cutting the laminate obtained in each example into a No. 3 dumbbell shape, and the sample was set in a tensile testing machine. The distance between the marked lines (initial dimension) was set to 20 mm, the sample was stretched under a condition of 23° C. at a tensile speed of 10 mm/min, and the surface resistance value (unit: Q) between the marked lines was measured using a tester (“CDM-2000D” (product name) manufactured by Custom Corporation) at each specific elongation rate.

The elongation rate is a value calculated using the following calculation formula.

Elongation rate (%) ((distance between marked lines after elongation (mm))−(initial dimension))/(initial dimension)×100

The table shows a surface resistance value R¹ when the elongation rate is 200% (at 200% elongation), that is, when the distance between the marked lines is 60 mm.

The table also shows a surface resistance value R² when the elongation rate is 300% (at 300% elongation), that is, when the distance between the marked lines is 80 mm.

In addition, the table shows a logarithmic value of the amount of resistance change per 1% of elongation (unit: Q/%) when the elongation rate changes from 0% to 300%, which is calculated using the following formula (4). R⁰ in the formula (4) indicates a surface resistance value when the elongation rate is 0% (at 0% elongation).

The case where a crack or rupture occurred in the film when stretched is indicated as “B (not achieved)”, and the case where the film could be elongated but the electrical conductivity could not be detected is indicated as “B (unmeasurable)”.

$$\begin{matrix}[ Equation 4 ] & \\ Logarithmic value of amount of resistance change per 1 \% of elongation = {Log}_{10} \times \frac{( {R}^{2} - {R}^{0} )}{300} & ( 4 )\end{matrix}$$

### (Stretching Test (2))

Using the same measurement method as in the stretching test (1), the surface resistance value (unit: Q) was measured by increasing the elongation rate in a stepwise manner. The elongation rate was increased by 25% each time from 50% to 100%, and increased by 50% each time when it exceeded 100%. The maximum value of the elongation rate for which the surface resistance value could be measured within a detectable range of the measuring device (1.0×10⁷Ω or less) was recorded as the maximum value of the elongation rate (unit: %) at 1.0×10⁷Ω or less.

### (Cyclic Stretching Test)

A cyclic stretching test was carried out in the same manner as in Example 1-1 described above, and the properties shown in the table were evaluated.

TABLE 9

| | | | Ex. 2-1 | Ex. 2-2 | Ex. 2-3 | Ex. 2-4 | Ex. 2-5 |
|---|---|---|---|---|---|---|---|
| Proportion of | (Meth)acrylic | (2-1) | 30 | 30 | 40 | 30 | 40 |
| conductive ink | polymer | (2-2) | | | | | |
| composition | composition | (2-3) | | | | | |
| (% by mass) | Comparative composition (2-4) | | | | | | |
| | Carbon black | CB1 | 8 | 5 | 5 | | |
| | (CB) | CB2 | | | | 8 | 8 |
| | | CB3 | | | | | |
| | Graphite | Graphite D2-1 | | 5 | 5 | 5 | |
| | material (D) | | | | | | |
| | Solvent (C) | C2-1 | 54 | 52 | 42 | 49 | 44 |
| | Dispersant (E) | E2-1 | 8 | 8 | 8 | 8 | 8 |
| | Total | | 100 | 100 | 100 | 100 | 100 |
| Solid content (% by mass) | | | 17.9 | 19.9 | 23.2 | 22.9 | 21.2 |
| Content of (meth)acrylic polymer (A) (% by mass) | | | 9.9 | 9.9 | 13.2 | 9.9 | 13.2 |
| Content of carbon black (CB) (% by mass) | | | 8 | 5 | 5 | 8 | 8 |
| (Meth)acrylic polymer (A) / solid content (% by mass) | | | 55.31 | 49.75 | 56.90 | 43.23 | 62.26 |
| Carbon black (CB) / solid content (% by mass) | | | 44.69 | 25.13 | 21.55 | 34.93 | 37.73 |
| Graphite material (D) / solid content (% by mass) | | | 0 | 25.13 | 21.55 | 21.83 | 0.00 |
| Viscosity (Pa · s) | | | 96 | 72 | 81 | 25 | 21 |
| Evaluation of | Volume resistivity (Ω · cm) | | 2.4 × 10⁻¹ | 3.4 × 10⁻² | 8.9 × 10⁻² | 4.8 × 10⁻² | 6.8 × 10⁻¹ |
| conductive | Adhesion | | A | A | A | A | A |
| film | Surface resistance value | | 8.5 × 10³ | 1.2 × 10³ | 2.5 × 10³ | 4.6 × 10³ | 9.6 × 10³ |
| | R⁰ (Ω) at 0% elongation | | | | | | |
| | Surface resistance value | | 8.5 × 10⁴ | 4.5 × 10⁴ | 9.8 × 10⁴ | 1.3 × 10⁵ | 2.3 × 10⁵ |
| | R¹ (Ω) at 200% elongation | | | | | | |
| | Surface resistance value | | 4.6 × 10⁶ | 7.8 × 10⁶ | 2.5 × 10⁶ | 1.3 × 10⁶ | 5.3 × 10⁶ |
| | R² (Ω) at 300% elongation | | | | | | |
| | Logarithmic value of amount | | 4.2 | 4.4 | 3.9 | 3.6 | 4.2 |
| | of resistance value change | | | | | | |
| | (Ω/%) from 0 to 300% | | | | | | |
| | Maximum value of elongation rate | | 400 | 350 | 400 | 450 | 450 |
| | (%) at 1.0 × 10⁷ Ω or less | | | | | | |
| | Surface resistance | At the start (0%) | 8.5 × 10³ | 1.2 × 10³ | 2.5 × 10³ | 4.6 × 10³ | 9.6 × 10³ |
| | value (Ω) during | At the end (0%) | 2.8 × 10⁴ | 1.7 × 10³ | 3.5 × 10³ | 5.3 × 10³ | 2.3 × 10⁴ |
| | cyclic stretching | Difference in | 2.0 × 10⁴ | 5.0 × 10² | 1.0 × 10³ | 7.0 × 10² | 1.3 × 10⁴ |
| | | surface | | | | | |
| | | resistance value | | | | | |
| | | before and after | | | | | |
| | | cyclic stretching | | | | | |
| | | 1^{st} cycle: at | 5.6 × 10⁴ | 2.0 × 10⁴ | 3.4 × 10⁴ | 2.4 × 10⁴ | 7.1 × 10⁴ |
| | | 100% elongation | | | | | |
| | | 100^{th} cycle: at | 1.0 × 10⁵ | 5.7 × 10⁴ | 6.6 × 10⁴ | 6.2 × 10⁴ | 9.2 × 10⁴ |
| | | 100% elongation | | | | | |

TABLE 10

| | | | Comp. | Comp. | Comp. | Comp. |
|---|---|---|---|---|---|---|
| | | | Ex. 2-1 | Ex. 2-2 | Ex. 2-3 | Ex. 2-4 |
| Proportion of | (Meth)acrylic | (2-1) | | | | |
| conductive ink | polymer | (2-2) | 30 | | | |
| composition | composition | (2-3) | | 20 | | |
| (% by mass) | Comparative composition (2-4) | | | | 30 | 50 |
| | Carbon black | CB1 | 8 | 8 | 8 | 5 |
| | (CB) | CB2 | | | | |
| | | CB3 | | | | |
| | Graphite | Graphite | | | | 10 |
| | material (D) | D2-1 | | | | |
| | Solvent (C) | C2-1 | 54 | 64 | 54 | 27 |
| | Dispersant (E) | E2-1 | 8 | 8 | 8 | 8 |
| | Total | | 100 | 100 | 100 | 100 |
| Solid content (% by mass) | | | 17.0 | 17.0 | 17.0 | 30.0 |
| Content of (meth)acrylic polymer (A) (% by mass) | | | 9.0 | 9.0 | 9.0 | 15.0 |
| | | | | | Comparative | Comparative |
| | | | | | resin | resin |
| Content of carbon black (CB) (% by mass) | | | 8 | 8 | 8 | 5 |
| (Meth)acrylic polymer (A) / solid content (% by mass) | | | 52.94 | 52.94 | 52.94 | 50.00 |
| Carbon black (CB) / solid content (% by mass) | | | 47.06 | 47.06 | 47.06 | 16.67 |
| Graphite material (D) / solid content (% by mass) | | | 0 | 0 | 0 | 33.33 |
| Viscosity (Pa · s) | | | 82 | 64 | 38 | 33 |
| Evaluation of | Volume resistivity (Ω · cm) | | 1.8 × 10⁻¹ | 2.3 × 10⁻¹ | 1.5 × 10⁻¹ | 2.2 × 10⁻² |
| conductive | Adhesion | | C | C | C | C |
| film | Surface resistance value | | 2.6 × 10³ | 7.5 × 10⁴ | 9.4 × 10² | 7.6 × 10² |
| | R⁰ (Ω) at 0% elongation | | | | | |
| | Surface resistance value | | 8.8 × 10⁶ | B (not | B (not | B (not |
| | R¹ (Ω) at 200% elongation | | | achieved) | achieved) | achieved) |
| | Surface resistance value | | B (not | B (not | B (not | B (not |
| | R² (Ω) at 300% elongation | | achieved) | achieved) | achieved) | achieved) |
| | Logarithmic value of amount | | — | — | — | — |
| | of resistance value change | | | | | |
| | (Ω/%) from 0 to 300% | | | | | |
| | Maximum value of elongation | | 250 | 100 | 75 | 75 |
| | rate (%) at 1.0 × 10⁷ Ω or less | | | | | |
| | Surface resistance | At the start (0%) | 2.6 × 10³ | 7.5 × 10⁴ | 9.4 × 10² | 7.6 × 10² |
| | value (Ω) during | At the end (0%) | B (not | B (not | B (not | B (not |
| | cyclic stretching | | achieved) | achieved) | achieved) | achieved) |
| | | Difference in | — | — | — | — |
| | | surface | | | | |
| | | resistance value | | | | |
| | | before and after | | | | |
| | | cyclic stretching | | | | |
| | | 1^{st} cycle: at | 3.7 × 10⁴ | 8.1 × 10⁶ | B (not | B (not |
| | | 100% elongation | | | achieved) | achieved) |
| | | 100^{th} cycle: at | B (not | B (not | B (not | B (not |
| | | 100% elongation | achieved) | achieved) | achieved) | achieved) |

TABLE 11

| | | | Comp. | Comp. | Comp. |
|---|---|---|---|---|---|
| | | | Ex. 2-5 | Ex. 2-6 | Ex. 2-7 |
| Proportion of | (Meth)acrylic polymer | (2-1) | 15 | 50 | 30 |
| conductive ink | composition | (2-2) | | | |
| composition | | (2-3) | | | |
| (% by mass) | Comparative composition (2-4) | | | | |
| | Carbon black (CB) | CB1 | 3 | 10 | |
| | | CB2 | | | |
| | | CB3 | | | 5 |
| | Graphite material (D) | Graphite D2-1 | 5 | 10 | 5 |
| | Solvent (C) | C2-1 | 72 | 22 | 52 |
| | Dispersant (E) | E2-1 | 5 | 8 | 8 |
| | Total | | 100 | 100 | 100 |
| Solid content (% by mass) | | | 12.95 | 36.5 | 19.9 |
| Content of (meth)acrylic polymer (A) (% by mass) | | | 4.95 | 16.5 | 9.9 |
| Content of carbon black (CB) (% by mass) | | | 3 | 10 | 5 |
| (Meth)acrylic polymer (A)/solid content (% by mass) | | | 38.22 | 45.21 | 49.75 |
| Carbon black (CB)/solid content (% by mass) | | | 23.17 | 27.40 | 25.13 |
| Graphite material (D)/solid content (% by mass) | | | 38.61 | 27.40 | 25.13 |
| Viscosity (Pa · s) | | | 66 | 100 | 24 |
| Evaluation of | Volume resistivity (Ω · cm) | | 8.9 × 10⁻¹ | 1.3 × 10⁻² | 4.4 × 10⁻¹ |
| conductive | Adhesion | | A | C | B |
| film | Surface resistance value R⁰ (Ω) at 0% elongation | | 1.2 × 10⁴ | 1.4 × 10³ | 3.3 × 10⁴ |
| | Surface resistance value R¹ (Ω) at 200% elongation | | 7.7 × 10⁵ | B (not | 9.2 × 10⁶ |
| | | | | achieved) | |
| | Surface resistance value R² (Ω) at 300% elongation | | B (not | B (not | B (not |
| | | | achieved) | achieved) | achieved) |
| | Logarithmic value of amount of resistance value | | — | — | — |
| | change (Ω/%) from 0 to 300% | | | | |
| | Maximum value of elongation rate (%) at 1.0 × 10⁷ | | 275 | 75 | 200 |
| | Ω or less | | | | |
| | Surface resistance | At the start (0%) | 1.2 × 10⁴ | 1.4 × 10³ | 3.3 × 10⁴ |
| | value (Ω) during | | | | |
| | cyclic stretching | At the end (0%) | B (not | B (not | B (not |
| | | | achieved) | achieved) | achieved) |
| | | Difference in surface | — | — | — |
| | | resistance value | | | |
| | | before and after | | | |
| | | cyclic stretching | | | |
| | | 1^{st} cycle: at 100% | 2.5 × 10⁵ | B (not | 7.8 × 10⁵ |
| | | elongation | | achieved) | |
| | | 100^{th} cycle: at 100% | B (not | B (not | B (not |
| | | elongation | achieved) | achieved) | achieved) |

As shown in Table 9, the conductive films of Examples 2-1 to 2-5 exhibited excellent electrical conductivity and adhesion to the base material. In addition, they were elastic and exhibited excellent electrical conductivity when stretched, the electrical conductivity was detectable even at 300% elongation, and the maximum value of the elongation rate was large at 1.0×10⁷Ω or less.

The conductive films of Examples 2-1 to 2-5 also exhibited excellent resistance to cyclic stretching, and the electrical conductivity could be detected both in a stretched state (100%) and in a non-stretched state (0%) even after 100 cycles of repeated stretching at an elongation rate of 100%. Furthermore, the electrical conductivity was excellent in stability when repeatedly stretched, and the difference in surface resistance value before and after the cyclic stretching test was small.

Further, in Examples 2-1 to 2-5, it was observed that the surface resistance value tended to increase as the elongation rate increased.

On the other hand, as shown in Tables 10 and 11, in Comparative Examples 2-1 and 2-2 in which the weight average molecular weight or hydroxyl value of the (meth)acrylic polymer (A) was outside the range of the present invention, and in Comparative Examples 2-3 and 2-4 in which a comparative resin (polyester) was used in place of the (meth)acrylic polymer (A), a crack or rupture occurred in the film when stretched in the stretching test and the cyclic stretching test.

In Comparative Example 2-5 in which the solid content of the conductive ink composition was too low, and in Comparative Example 2-6 in which the solid content was too high, a crack or rupture occurred in the film during the stretching test and the cyclic stretching test.

In Comparative Example 2-7 in which the specific surface area of carbon black (CB) was small and the aggregate diameter was large, a crack or rupture occurred in the film during the stretching test and the cyclic stretching test.

1. A conductive ink composition comprising: a (meth)acrylic polymer (A) and silver particles (B), wherein
the (meth)acrylic polymer (A) has a glass transition temperature of 0° C. or less, a weight average molecular weight of 500,000 or more, and a hydroxyl value of more than 50 mgKOH/g,
the silver particles (B) have a specific surface area of 0.5 to 3.0 m²/g, a 50% average particle diameter of 0.5 to 14.0 m, and a maximum particle diameter of 8 m or more, and a solid content is from 50 to 80% by mass.

2. The conductive ink composition according to claim 1, wherein
the (meth)acrylic polymer (A) has a glass transition temperature of more than −50° C. and less than −30° C., and a weight average molecular weight of 500,000 to 990,000.

3. The conductive ink composition according to claim 1, wherein
a content of a unit (a1) based on a hydroxyl group-containing monomer is from 20 to 40% by mass with respect to all units constituting said (meth)acrylic polymer (A).

4. The conductive ink composition according to claim 1, which has a viscosity at 23° C. of 20 to 50 Pa s.

5. A conductive film obtained by drying a coating film of the conductive ink composition according to claim 1.

6. The conductive film according to claim 5, which is used for an electrode or wiring that requires elasticity in an electronic device.

7. The conductive film according to claim 5, which is used for a detection part, electrode, or wiring of a variable resistance sensor.

8. A conductive ink composition comprising: a (meth)acrylic polymer (A) and carbon black (CB), wherein
the (meth)acrylic polymer (A) has a glass transition temperature of 0° C. or less, a weight average molecular weight of 500,000 or more, and a hydroxyl value of more than 50 mgKOH/g,
the carbon black (CB) has a specific surface area of 50 ma/g or more and an aggregate diameter of 400 nm or less, and
a solid content is from 15 to 30% by mass.

9. The conductive ink composition according to claim 8, wherein
the (meth)acrylic polymer (A) has a glass transition temperature of more than −50° C. and less than −30° C., and a weight average molecular weight of 500,000 to 990,000.

10. The conductive ink composition according to claim 8, wherein
a content of a unit (a1) based on a hydroxyl group-containing monomer is from 20 to 40% by mass with respect to all units constituting said (meth)acrylic polymer (A).

11. The conductive ink composition according to claim 8, which has a viscosity at 23° C. of 20 to 100 Pa s.

12. A conductive film obtained by drying a coating film of the conductive ink composition according to claim 8.

13. The conductive film according to claim 12, which is used in an electronic device for an electrode or wiring that requires elasticity.

14. The conductive film according to claim 12, which is used for a detection part, electrode, or wiring of a variable resistance sensor.

15. The conductive ink composition according to claim 1, wherein
a content of a unit (a2) based on a (meth)acrylate having an alkyl group of 4 to 12 carbon atoms is from 46 to 64% by mass with respect to all units constituting said (meth)acrylic polymer (A).

16. The conductive ink composition according to claim 1, wherein
a content of a unit (a3) based on a (meth)acrylate having an alkyl group of 1 to 3 carbon atoms is from 6 to 19% by mass with respect to all units constituting said (meth)acrylic polymer (A).

17. The conductive ink composition according to claim 1, wherein
a content of a unit (a4) based on a carboxy group-containing monomer is from 0.05 to 0.35% by mass with respect to all units constituting said (meth)acrylic polymer (A).

18. The conductive ink composition according to claim 8, wherein
a content of a unit (a2) based on a (meth)acrylate having an alkyl group of 4 to 12 carbon atoms is from 46 to 64% by mass with respect to all units constituting said (meth)acrylic polymer (A).

19. The conductive ink composition according to claim 8, wherein
a content of a unit (a3) based on a (meth)acrylate having an alkyl group of 1 to 3 carbon atoms is from 6 to 19% by mass with respect to all units constituting said (meth)acrylic polymer (A).

20. The conductive ink composition according to claim 8, wherein
a content of a unit (a4) based on a carboxy group-containing monomer is from 0.05 to 0.35% by mass with respect to all units constituting said (meth)acrylic polymer (A).
